(19) United States
(12) Patent Application Publication
(10) Pub. No.: US 2016/0343971 A1
(43) Pub. Date: Nov. 24, 2016

(54) LIGHT-EMITTING DEVICE AND METHOD OF PRODUCING A LIGHT-EMITTING DEVICE

(71) Applicant: OSRAM OLED GMBH, Regensburg (DE)

(72) Inventors: Stefan Dechand, Regensburg (DE); Sarah Seidel, Theuma (DE); Dieter Musa, Wenzenbach (DE); Michael Popp, Freising (DE)

(21) Appl. No.: 15/112,517

(22) PCT Filed: Jan. 20, 2015
(86) PCT No.: PCT/EP2015/050984

§ 371 Date: Jul. 19, 2016

(30) Foreign Application Priority Data
Jan. 23, 2014 (DE) 10 2014 100 770.0

(51) Int. Cl. H01L 51/52; H01L 51/56; H01L 27/32

(52) U.S. Cl. CPC H01L 51/525; H01L 27/3276; H01L 27/3288; H01L 51/5212; H01L 51/56; H01L 51/5246; H01L 2251/5361

(57) ABSTRACT

A light-emitting device includes a substrate having a substrate upper side, a layer sequence arranged on the substrate upper side and having at least one active, light-emitting, organic layer, wherein the layer sequence includes a plurality of emission regions that emit light, current-conducting rails which are a part of the layer sequence, wherein, in a plan view of the substrate upper side, the emissionr egions of the layer sequence are arranged next to the current-conducting rails, an encapsulation glass, wherein the layer sequence is arranged between the substrate and the encapsulation glass, and spacers formed as elevations on an encapsulation glass underside and facing towards the layer sequence of the encapsulation glass, wherein, in a plan view of the substrate upper side, the spacers at least partly overlap with the current-conducting rails, and the spacers prevent direct contact between the encapsulation glass and the layer sequence in the emission regions.

### TECHNICAL FIELD

This disclosure relates to a light-emitting device and a method of producing a light-emitting device.

### BACKGROUND

It could be helpful to provide a light-emitting device that is damaged to the least possible extent in the event of mechanical loading and a method of producing a light-emitting device in which the device is damaged to the least possible extent during the production process.

### SUMMARY

We provide a light-emitting device including a substrate having a substrate upper side, a layer sequence arranged on the substrate upper side and having at least one active, light-emitting, organic layer, wherein the layer sequence includes a plurality of emission regions that emit light, current-conducting rails which are a part of the layer sequence, wherein, in a plan view of the substrate upper side, the emission regions of the layer sequence are arranged next to the current-conducting rails, an encapsulation glass, wherein the layer sequence is arranged between the substrate and the encapsulation glass, and spacers formed as elevations on an encapsulation glass underside and facing towards the layer sequence of the encapsulation glass, wherein, in a plan view of the substrate upper side, the spacers at least partly overlap with the current-conducting rails, and the spacers prevent direct contact between the encapsulation glass and the layer sequence in the emission regions.

We also provide a light-emitting device including a substrate having a substrate upper side, a layer sequence arranged on the substrate upper side and having at least one active, light-emitting, organic layer, wherein the layer sequence includes a plurality of emission regions that emit light, current-conducting rails which are a part of the layer sequence, wherein, in a plan view of the substrate upper side, the emission regions of the layer sequence are arranged next to the current-conducting rails, and the current-conducting rails intersect at intersection points, an encapsulation glass, wherein the layer sequence is arranged between the substrate and the encapsulation glass, spacers formed as elevations on an encapsulation glass underside and facing towards the layer sequence of the encapsulation glass, wherein the spacers are formed as buffer points, wherein the buffer points are mutually spaced-apart, dome-shaped elevations arranged in a matrix in a regular pattern on the encapsulation glass underside, in a plan view of the substrate upper side, each spacer at least partly overlaps with an intersection point of the current-conducting rails, and the spacers prevent direct contact between the encapsulation glass and the layer sequence in the emission regions.

We further provide a method of producing the light-emitting device including a substrate having a substrate upper side, a layer sequence arranged on the substrate upper side and having at least one active, light-emitting, organic layer, wherein the layer sequence includes a plurality of emission regions that emit light, current-conducting rails which are a part of the layer sequence, wherein, in a plan view of the substrate upper side, the emission regions of the layer sequence are arranged next to the current-conducting rails, an encapsulation glass, wherein the layer sequence is arranged between the substrate and the encapsulation glass, and spacers formed as elevations on an encapsulation glass underside and facing towards the layer sequence of the encapsulation glass, wherein, in a plan view of the substrate upper side, the spacers at least partly overlap with the current-conducting rails, and the spacers prevent direct contact between the encapsulation glass and the layer sequence in the emission regions, including providing a substrate having a substrate upper side, applying a layer sequence to the substrate upper side, wherein an edge region of the substrate upper side is provided at least partly to be free from the layer sequence, providing an encapsulation glass having an encapsulation glass underside, applying an adhesive layer to the encapsulation glass underside, applying spacers to the encapsulation glass underside so that the spacers are bordered by the adhesive layer, and joining the substrate and the encapsulation glass together so that the substrate upper side and the encapsulation glass underside face towards one another and the adhesive layer is arranged in the edge region of the substrate upper side.

### BRIEF DESCRIPTION OF THE DRAWINGS

FIGS. 1 and 2 show schematic side views of examples of the light-emitting device.

FIGS. 3a and 3b show schematic plan views of examples of the light-emitting device.

FIGS. 4a to 4c show schematic illustrations of individual method steps of the method of producing a light-emitting device.

### DETAILED DESCRIPTION

Our light-emitting device may comprise a substrate having a substrate upper side. The substrate preferably comprises a radiation-transmissive, in particular transparent or milky-cloudy material, e.g., glass or synthetic materials. Preferably, the substrate consists of such a material. In particular, the substrate can be provided for use in coupling-out light from the light-emitting device. The substrate upper side is, e.g., a major side of the substrate.

The light-emitting device may comprise a layer sequence arranged on the substrate upper side. The layer sequence can comprise, e.g., at least one active, light-emitting, organic layer. The layer sequence further comprises one or a plurality of emission regions that emit light. The emission regions can be understood to be the regions which in a plan view of the device appear to be light-emitting. In particular, the entire active organic layer can be light-emitting, but only from some regions does the light actually travel to the observer. These regions are then, e.g., the emission regions. The different emission regions are preferably operated in parallel or simultaneously. In other words, the different emission regions are preferably driven together, e.g., via a single switch, rather than separately.

The layer sequence has, e.g., a lateral extent in parallel with the substrate upper side of ≧2 cm or ≧5 cm or ≧10 cm. Alternatively or in addition, the lateral extent of the layer sequence is ≦35 cm, e.g., ≦30 cm or ≦20 cm. The emission regions have, e.g., a lateral extent of at least 100 μm or 1 mm or 2 mm. Alternatively or in addition, the lateral extent of the emission regions is ≦5 mm, or ≦4 mm or ≦3 mm.

In addition to the active organic layer, the layer sequence can also comprise further organic layers such as, e.g., electron injection layers or hole injection layers. Furthermore, it is possible for the layer sequence to comprise a plurality of active organic layers all emitting electromagnetic radiation, and comprise, e.g., different emitters emitting in different wavelength ranges. The thicknesses of the individual organic layers is, e.g., at least 10 nm or ≧100 nm or ≧200 nm. Alternatively or in addition, the thicknesses of the individual organic layers are ≦500 nm or ≦200 nm or ≦100 nm.

The light-emitting device may comprise current-conducting rails. The current-conducting rails are a part of the layer sequence. If the light-emitting device is viewed in a plan view of the substrate upper side, the emission regions of the layer sequence are preferably arranged next to or between the current-conducting rails. In a plan view of the substrate upper side, the current-conducting rails can form, e.g., a grid, e.g., a rectangular or hexagonal grid. The current-conducting rails then include rectangular or hexagonal regions of the layer sequence. These regions can be emission regions. In particular, it is possible that no light travels to the observer from the regions of the active organic layer which in a plan view overlap with the current-conducting rails, e.g., because the active organic layer in these regions does not emit any light or because the current-conducting rails act in a light-absorbing manner.

The current-conducting rails preferably comprise a metallic material such as gold or silver or aluminum or platinum, or consist at least of one of such a material. In particular, it is possible for the current-conducting rails to comprise a layer sequence of a plurality of metallic materials, e.g., a chromium-aluminum-chromium layer sequence. However, a molybdenum-aluminum layer sequence is also possible. The current-conducting rails further comprise, e.g., a width of ≧60 μm or ≧70 μm or ≧80 μm. Alternatively or in addition, the width of the current-conducting rails is ≦150 μm or ≦90 μm or ≦95 μm. The thickness of the current-conducting rails is, e.g., at least 3 μm or ≧3.5 μm or ≧4 μm. Alternatively or in addition, the thickness of the current-conducting rails is ≦6 μm or ≦5.5 μm or ≦5 μm. The width or the thickness of the current-conducting rails can be understood to be the average or the maximum or minimum width or thickness.

The light-emitting device may comprise an encapsulation glass. The layer sequence is enclosed between the encapsulation glass and the substrate. In a plan view of the substrate upper side, the encapsulation glass thus partly or completely covers the layer sequence. The encapsulation glass can comprise a light-transmissive, e.g., milky-cloudy or transparent material, e.g., a silicate glass or a synthetic material, or can consist of such a material. Preferably, the encapsulation glass is formed as a platelet comprising two plane-parallel major sides. The major sides then extend, e.g., in parallel to the substrate upper side.

The light-emitting device may comprise spacers. The spacers are formed as elevations on an encapsulation glass underside, e.g., a major side facing towards the layer sequence of the encapsulation glass. In a plan view of the substrate upper side, the spacers preferably partly or completely overlap with the current-conducting rails. In particular, the spacers prevent direct contact between the encapsulation glass and the layer sequence, specifically in the emission regions of the layer sequence.

The spacers can be, e.g., a structuring of the encapsulation glass. However, in particular, the spacers can also be applied directly to the encapsulation glass and can consist of a different material than the material of the encapsulation glass.

The light-emitting device may comprise a substrate having a substrate upper side. Arranged on the substrate upper side is a layer sequence comprising at least one active, light-emitting, organic layer. Moreover, the layer sequence comprises one or a plurality of emission regions that emit light. The layer sequence further comprises current-conducting rails, wherein in a plan view of the substrate upper side the emission regions of the layer sequence are arranged between or next to the current-conducting rails. Furthermore, the light-emitting device comprises an encapsulation glass, wherein the layer sequence is arranged between the substrate and the encapsulation glass. Spacers are applied to the encapsulation glass, wherein the spacers are formed as elevations on an encapsulation glass underside facing towards the layer sequence. In a plan view of the substrate upper side, the spacers at least partly overlap with the current-conducting rails of the layer sequence. The spacers prevent direct contact between the encapsulation glass and the layer sequence in the region of the emission regions.

The layer sequence is preferably not in direct contact with the encapsulation glass. Instead, it is possible that a cavity is formed between the layer sequence and the encapsulation glass in the region of the emission regions, the cavity being filled, e.g., with a gas. Therefore, during production of the light-emitting device foreign particles enclosed between the layer sequence and the encapsulation glass are not pressed into the layer sequence or are pressed therein to a lesser extent. This reduces damage to the light-emitting device during the production process. After the production process, the light-emitting device is also less susceptible to damage. By virtue of the fact that the spacers are preferably provided above or opposite the current-conducting rails, in the event of a mechanical loading on the light-emitting device, the spacers are preferably pressed only onto the regions of the layer sequence in which current-conducting rails are provided. Although in these regions the layer sequence, in particular the active organic layer, can then be adversely affected, these regions are preferably not provided to emit light. Instead, the light-emitting emission regions advantageously lie next to the current-conducting rails. Therefore, in the event of a mechanical loading, the emission regions are not brought into contact with the spacers and are thus also not damaged.

The spacers may be formed as buffer points. The buffer points are mutually spaced-apart dome-like elevations on the encapsulation glass underside.

The buffer points on the encapsulation glass underside have, e.g., a lateral extent along the encapsulation glass underside of at least 50 μm or 100 μm or 150 μm. Alternatively or in addition, the lateral extent of the buffer points is ≦300 μm or ≦250 μm or ≦200 μm. The thickness of the buffer points perpendicular to the encapsulation glass underside is preferably at least 10 μm or 20 μm or 30 μm. Alternatively or in addition, the thickness of the buffer points is ≦50 μm or ≦40 μm or ≦30 μm. The lateral extent of the buffer points is preferably at the most 5% or at the most 2% or at the most 1% or at the most 0.1% of the lateral extent of the encapsulation glass.

The current-conducting rails may intersect at intersection points. At such an intersection point, at least two or three or four or five current-conducting rails intersect. The spacing between two adjacent intersection points of the current-conducting rails is, e.g., at least 1 mm or 2 mm or 3 mm. Alternatively or in addition, the spacing between two adjacent intersection points is ≦5 mm or ≦4 mm or ≦3 mm.

In a plan view of the substrate, upper side the buffer points are arranged on the encapsulation glass underside preferably such that they at least partly or completely overlap with the intersection points of the current-conducting rails. Preferably, each buffer point at least partly or completely overlaps with only one intersection point.

Such a structure is particularly advantageous if the light-emitting device is mechanically loaded. If, e.g., pressure is exerted upon the encapsulation glass or upon the substrate, the spacers in the form of buffer points press preferably only onto regions of the layer sequence in which the current-conducting rails intersect. On the one hand, these intersection points can form mechanically particularly stable regions of the device, on the other hand these regions are generally not provided to emit electromagnetic radiation. Damage to the active organic layer in the region of the intersection points thus preferably continues to have no effect upon the optical properties of the light-emitting device.

The current-conducting rails may be arranged between the active organic layer and the substrate. The current-conducting rails can lie on the substrate upper side, wherein further layers or materials can certainly be located between the current-conducting rails and the substrate. The active organic layer is placed, e.g., onto the current-conducting rails and can conform to the structure of the current-conducting rails. In other words, as seen from the substrate upper side the active organic layer can be located at a higher position in the region of the current-conducting rails than in the regions between the current-conducting rails, e.g., in the emission regions. Alternatively, it is also possible for the current-conducting rails to be countersunk in the substrate so that the current-conducting rails and the substrate terminate flush with one another at the substrate upper side. In this case, the active organic layer can be characterized, e.g., by two major sides extending in a planar manner and in parallel with the substrate upper side.

The layer sequence may comprise a first electrode, e.g., an anode. The first electrode is arranged, e.g., between the current-conducting rails and the substrate. The first electrode can comprise the same material as or a different material from the current-conducting rails. In particular, the first electrode comprises a transparent conductive material, e.g., a transparent oxide material, TCO for short such as, e.g., indium tin oxide, ITO for short.

The layer sequence may comprise a second electrode, e.g., a cathode. The second electrode can be arranged, e.g., downstream of the active organic layer in a direction away from the substrate upper side. In this case, the active organic layer lies between the second electrode and the substrate. The second electrode can comprise, e.g., a metal such as gold or silver or aluminum, or can consist of such a material. In particular, the cathode can comprise a material which is reflective to the light emitted by the active organic layer.

In the two examples above, the light-emitting device is preferably formed as a bottom emitter. In other words, the light from the active organic layer is coupled out of the light-emitting device via the transparent conductive anode and via the substrate which in this case is transparent.

However, it is also possible for the cathode to comprise a conductive transparent material and for the anode to comprise a reflective material. It is further possible for the light-emitting device to be formed as a top emitter, wherein, e.g., an electrode arranged between the active organic layer and the substrate is formed to be reflective and accordingly an electrode arranged downstream of the active organic layer in a direction away from the substrate upper side can be transparent to the light emitted by the active organic layer. In this case, the light from the active organic layer is coupled out from the light-emitting device, e.g., via the encapsulation glass.

The thicknesses of the anode and the cathode are, e.g., at least 50 nm or 100 nm or 200 nm. Alternatively or in addition, the thicknesses of the anode and the cathode are ≦500 nm or ≦300 nm or ≦250 nm.

The buffer points may be arranged matrix-like on the encapsulation glass underside of the encapsulation glass. Such an arrangement proves to be particularly advantageous if the current-conducting rails form a regular grid. To ensure that in a plan view of the substrate upper side the buffer points overlap, e.g., with the intersection points of the current-conducting rails, the buffer points can likewise comprise a regular, in particular matrix-like, arrangement. For example, hexagonal or rectangular matrix patterns are possible.

The spacers on the encapsulation glass may be at least temporarily not in direct contact with the layer sequence. In particular, the light-emitting device can be designed such that a direct contact between the spacers and the layer sequence only occurs when the light-emitting device is loaded mechanically, e.g., under pressure on the encapsulation glass or on the substrate. Furthermore, the light-emitting device can, however, also be designed such that at least in some regions the spacers are permanently in direct contact with the layer sequence even without any mechanical loading on the device.

The substrate upper side may comprise an edge region at least partly free from the layer sequence. The edge region of the substrate upper side can be, e.g., a region which adjoins lateral surfaces of the substrate, wherein the lateral surfaces extend transversely with respect to the substrate upper side and define the substrate in the direction in parallel with the substrate upper side. Preferably, an adhesive layer is applied to the edge region of the substrate upper side. The adhesive layer preferably covers regions of the edge region free from the layer sequence. Furthermore, the adhesive layer contacts, in particular in direct contact, the encapsulation glass underside of the encapsulation glass, and thereby establishes a mechanical connection between the substrate and the encapsulation glass. In a plan view of the substrate upper side, the adhesive layer forms, e.g., a continuous, contiguous path around the layer sequence. The layer sequence is thus defined by the adhesive layer, e.g., in all directions in parallel with the substrate upper side, but does not necessarily have to be in direct contact with the adhesive layer. In particular, the adhesive layer can connect the encapsulation glass and the substrate together such that an air-tight intermediate space is produced between the encapsulation glass and the substrate. For example, the layer sequence is then arranged in the intermediate space.

The adhesive layer comprises, e.g., a resin, in particular the adhesive layer can be a UV-curing adhesive. Moreover, the adhesive layer preferably comprises a thickness perpendicular to the substrate upper side of at least 10 μm or 30 μm or 50 μm. Alternatively or in addition, the thickness of the adhesive layer is ≦80 μm, e.g., ≦70 μm or ≦60 μm. The lateral extent of the adhesive layer in parallel with the substrate upper side, in particular the width of the path from the adhesive layer which extends around the layer sequence is, e.g., at least 1 mm or 5 mm or 1 cm. Alternatively or in addition, the lateral extent of the adhesive layer is ≦2 cm, e.g., ≦1.5 cm or ≦1.2 cm.

An absorption material may be introduced between the layer sequence and the encapsulation glass. The absorption material can be used to capture and absorb water molecules and/or oxygen molecules that could damage the layer sequence, in particular the organic active layer. To this end, the absorption material can comprise an oxidizable material such as, e.g., an alkali metal or an alkaline earth metal. For example, the absorption material can comprise magnesium, calcium, barium, cesium, cobalt, yttrium, lanthanum and/or rare earth metals. In particular, metal oxide compounds such as calcium oxide, barium oxide or magnesium oxide can also be used as the absorption material. The absorption material is preferably a liquid absorption material which is introduced, e.g., in droplet form between the layer sequence and the encapsulation glass. By using such a liquid absorption material, it is possible to prevent the absorption material from being pressed into the layer sequence in the event of a mechanical loading on the light-emitting device.

The adhesive layer and the spacers may be produced from the same material. In particular, the material of the adhesive layer and the spacers differs from the material of the encapsulation glass. By using the same material for the adhesive layer and the spacers, the adhesive layer and the spacers can, for example, be applied to the encapsulation glass in a common step during the production process.

The layer sequence may comprise a thin-film encapsulation. The thin-film encapsulation partly or completely covers all of the sides of the layer sequence not covered by the substrate upper side of the substrate. In particular, the sides of the layer sequence are completely covered with the thin-film encapsulation to such an extent that only the regions of the layer sequence which for contacting purposes must be free remain uncovered by the thin-film encapsulation. As a result, the thin-film encapsulation acts as additional protection for the layer sequence, in particular the active organic layer, against reactions and/or oxidation processes with the surrounding area.

The thin-film encapsulation is, e.g., a layer of silicon oxide or silicon nitride or aluminum nitride deposited onto the layers of the layer sequence preferably by chemical vapor deposition, CVD for short, or physical vapor deposition, PVD for short, or sputtering. In particular, the thin-film encapsulation comprises a layer thickness of at the most 50 nm or 100 nm or 200 nm. Alternatively or in addition, the thickness of the thin-film encapsulation is ≦1000 nm or ≦400 nm or ≦300 nm.

The current-conducting rails may at least be partly covered with an insulating material. In particular, at least 80% or 90% or 95% of the side of each current-conducting rail facing away from the substrate is covered with the insulating material. Furthermore, it is also possible for lateral surfaces of the current-conducting rails extending transversely with respect to the substrate upper side to be at least partly coated with the insulating material. If the spacers are pressed onto the layer sequence, e.g., by reason of a mechanical pressure on the light-emitting device, the metallic cathode could thus be pressed through the active organic layer onto the current-conducting rails. Without the insulating material on the current-conducting rails, the light-emitting device could possibly short-circuit and fail.

The current-conducting rails may be embedded in the substrate so that the current-conducting rails terminate, e.g., flush with the substrate on the substrate upper side. Preferably, the insulating material is then arranged in the form of rails between the active organic layer and the second electrode so that in a plan view of the substrate upper side the current-conducting rails at least partly overlap with the insulating material.

We also provide a method of producing a light-emitting device. The light-emitting device described here can be produced by the method described herein. That is to say that all of the features disclosed in conjunction with the production method are also disclosed for the light-emitting device, and vice versa.

A substrate having a substrate upper side may be provided. In a subsequent step, a layer sequence is applied to the substrate upper side. An edge region of the substrate upper side is to remain at least partly free from the layer sequence. Therefore, no layer sequence is applied in this region or the layer sequence is then removed in a subsequent step.

The application of the layer sequence can include a plurality of intermediate steps. For example, a transparent conductive anode, a grid of current-conducting rails, one or a plurality of active organic layers, a reflective cathode and a thin-film encapsulation are applied consecutively to the substrate upper side.

An encapsulation glass having an encapsulation glass underside may be provided. An adhesive layer can be applied to the encapsulation glass underside. Furthermore, spacers can be applied to the encapsulation glass underside. Subsequently, e.g., the substrate and the encapsulation glass are then joined together, wherein the substrate upper side and the encapsulation glass underside face towards one another. The joining procedure is effected preferably such that the adhesive layer is arranged in the edge region of the substrate upper side.

The spacers are advantageously applied such that after the substrate and the encapsulation glass have been joined together, spacers partly cover the current-conducting rails of the layer sequence in a plan view of the substrate upper side.

The spacers and the adhesive layer may be applied to the encapsulation glass underside in a common screen printing process or ink-jet process or pad printing process. Preferably, the spacers and the adhesive layer comprise the same material. However, it is also possible for the spacers to be introduced directly into the encapsulation glass, e.g., by structuring the encapsulation glass.

A light-emitting device and method described herein to produce a light-emitting device will be explained in greater detail hereinafter with the aid of examples. Like reference numerals designate like elements in the individual figures. However, none of the references are illustrated to scale; rather individual elements can be illustrated excessively large for improved understanding.

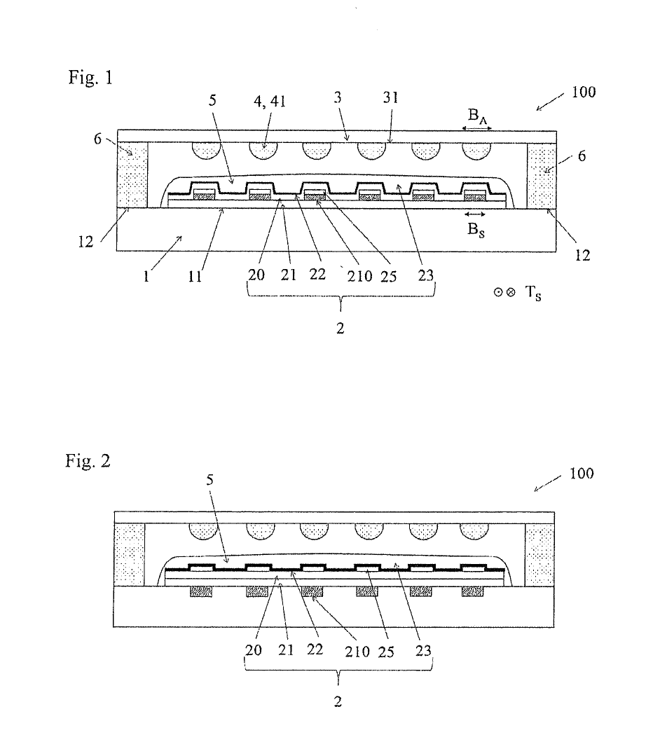

FIG. 1 shows a sectional illustration of a light-emitting device 100. A layer sequence 2 is applied to a substrate upper side 11 of a substrate 1. The substrate 1 can be, e.g., transparent to visible light. The layer sequence 2 comprises a transparent conductive electrode 21, e.g., an anode 21 applied to the substrate upper side 11. The transparent conductive anode 21 consists, e.g., of indium tin oxide, ITO for short.

Current-conducting rails 210 are arranged downstream of the anode 21 in a direction away from the substrate upper side 11. The current-conducting rails 210 each have a main extension direction T_{S} which in FIG. 1 extends in each case perpendicularly to the drawing plane. The main extension directions T_{S} of the current-conducting rails 210 extend in parallel with the substrate upper side 11 of the substrate 1. In FIG. 1, the widths B_{S} of the current-conducting rails 210 in the direction perpendicular to the main extension directions T_{S} are, e.g., 60 μm. The thicknesses of the current-conducting rails 210 perpendicular to the substrate upper side 11 are, e.g., 4 μm in each case. Furthermore, the current-conducting rails are produced, e.g., from a chromium-aluminum-chromium layer sequence.

A layer of an insulating material 25 is arranged downstream of the current-conducting rails 210 in a direction away from the substrate upper side 11. The insulating material 25 covers, e.g., at least 99% of the side of the current-conducting rails 210 facing away from the substrate 11. However, in addition the insulating material 25 can also cover, e.g., at least 95% of lateral surfaces of the current-conducting rails 210 extending transversely with respect to the substrate upper side 11. The insulating material 25 prevents a possible short-circuit between the anode 21 and a further electrode in the event of a mechanical loading on the light-emitting device 100. The insulating material 25 is, e.g., a layer of a photoresist or an epoxy resin. The average or maximum or minimum thickness of the layer of the insulating material 25 is, e.g., 1 μm to 6 μm.

An active organic layer 20 is arranged downstream of the transparent anode 21 and the current-conducting rails 210 in a direction away from the substrate upper side 11. The active organic layer 20 is placed over the current-conducting rails 210 such that the active organic layer 20, as seen from the substrate upper side 11, is located at a higher position in regions of the current-conducting rails 210 than in the regions between the current-conducting rails 210. In FIG. 1, emission regions 5 of the layer sequence 2 which are provided for light emission are arranged between the current-conducting rails 210. Light generated by the active organic layer 20 in the emission regions 5 can be coupled out of the light-emitting device 100, e.g., via the transparent anode 21 and via the transparent substrate 1. In other words, the device 100 in FIG. 1 is formed as a bottom emitter. In particular, the regions of the organic active layer 20 which, as seen from the substrate upper side 11, are arranged above the current-conducting rails 210 are not provided for emitting light.

In FIG. 1, the layer sequence 2 further comprises a second electrode 22, e.g., a cathode 22. The cathode 22 is arranged downstream of the active organic layer 20 in a direction away from the substrate upper side 11. In FIG. 1, the cathode 22 comprises, e.g., a reflective metal such as aluminum or silver.

Furthermore, the layer sequence 2 in FIG. 1 is provided with a thin-film encapsulation 23, of, e.g., silicon oxide. The thin-film encapsulation 23 covers preferably all of the sides of the layer sequence 2 which are not covered by the substrate upper side 11. In particular, the thin-film encapsulation 23 can completely cover all of the sides of the layer sequence 2 in the regions which do not have to remain uncovered for the purpose of external electrical contacting. The layer thickness of the thin-film encapsulation 23 is, e.g., 100 nm. The thin-film encapsulation 23 is used in particular for protecting the layers in the layer sequence 2, e.g., the active organic layer 20, against reactions and oxidation processes with the surrounding area.

The layer sequence 2 in FIG. 1 thus comprises the anode 21, the current-conducting rails 210, the insulating material 25, the active organic layer 20, the cathode 22 and the thin-film encapsulation 23. The layer sequence 2 has, e.g., a lateral extent along the substrate upper side 11 of 20 cm, the lateral extent of the emission regions 5 is, e.g., 3 mm in each case.

According to the example in FIG. 1, the layer sequence 2 does not cover the entire substrate upper side 11. Rather, the substrate upper side 11 in edge regions 12 is free from the layer sequence 2. The edge regions 12 of the substrate upper side 11 adjoin lateral surfaces of the substrate 1, wherein the lateral surfaces of the substrate 1 define the substrate 1 in the direction in parallel with the substrate upper side 11. An adhesive layer 6 is provided on the edge regions 12 of the substrate upper side 11. The adhesive layer 6 has, e.g., a lateral extent in parallel with the substrate upper side 11 of 0.5 cm. The thickness of the adhesive layers 6 perpendicular to the substrate upper side 11 is e.g., 50 μm. The adhesive layers 6 in FIG. 1 form a mechanical connection between the substrate 1 and an encapsulation glass 3 which is arranged downstream of the layer sequence 2 in a direction away from the substrate upper side 11. In particular, the adhesive layers 6 can be provided for holding the encapsulation glass 3 at a fixed spacing with respect to the layer sequence 2.

In FIG. 1, the encapsulation glass 3 is spaced apart from the substrate 2 by the adhesive layers 6 to such an extent that the encapsulation glass 3 and the layer sequence 2 are not in direct contact. In particular, there is no direct contact between the encapsulation glass 3 and the layer sequence 2 in the emission regions 5. Rather, an intermediate space is located between the encapsulation glass 3 and the layer sequence 2. The intermediate space can be filled, e.g., with an inert gas such as argon. Alternatively or in addition, the intermediate space can comprise an absorption material, in particular a liquid absorption material.

The encapsulation glass 3 is formed as a platelet comprising two plane-parallel major sides. The major sides extend in parallel with the substrate upper side 11. In FIG. 1, an encapsulation glass underside 31 facing towards the substrate 1 directly contacts the adhesive layers 6. Furthermore, spacers 4 are applied to the encapsulation glass underside 31. The spacers 4 are produced, e.g., from the same material as the adhesive layer 6. Furthermore, in FIG. 1 the spacers 4 are arranged on the encapsulation glass underside 31 such that in a plan view of the substrate upper side 11 the spacers 4 overlap with the current-conducting rails 210. Furthermore, the average or maximum or minimum width B_{A} of the spacers 4 is greater than the width B_{S} of the current-conducting rails 210. Alternatively, the width B_{A} of the spacers 4 can, however, also be less than the width B_{S} of the current-conducting rails 210. The width B_{A} of the spacers 4 is defined, e.g., as the extent of the spacers 4 perpendicular to the main extension direction T_{S} of the current-conducting rails 210.

The spacers 4 can be formed in particular as buffer points 41, wherein a buffer point 41 is a dome-like elevation from the encapsulation glass underside 31.

In FIG. 1, the adhesive layer 6 comprises such a thickness that the spacers 4 are not in direct contact with the layer sequence 2. The spacers 4 have, e.g., an average or maximum or minimum thickness perpendicular to the encapsulation glass underside 31 of 20 μm. Alternatively, it is also possible, however, for the spacers 4 to be in direct contact with the layer sequence 2, e.g., in that the spacers 4 press onto the thin-film encapsulation 23.

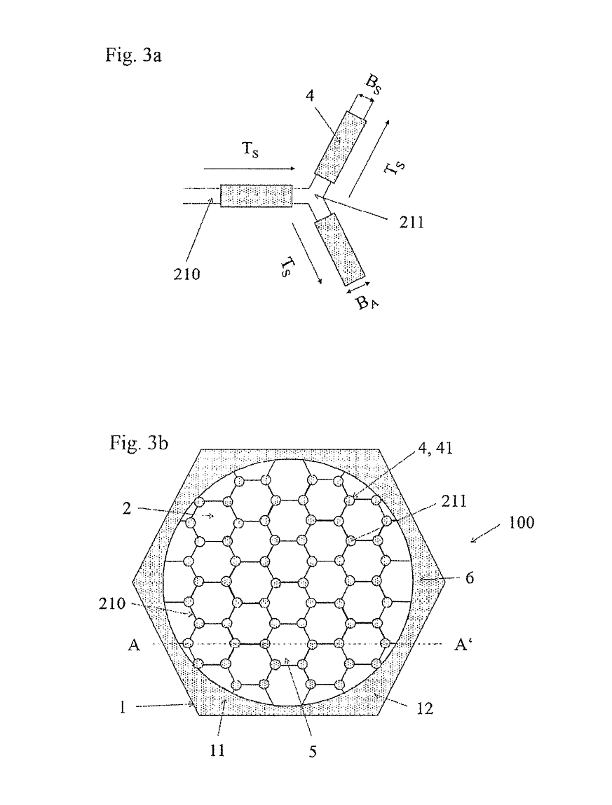

FIG. 2 shows a further example of the light-emitting device 100. In comparison with FIG. 1, in the example in accordance with FIG. 2 the current-conducting rails 210 are embedded in the substrate 1 so that the current-conducting rails 210 terminate flush with the substrate 1 on the substrate upper side 11. The transparent anode 21 is placed onto the current-conducting rails 210 in a direction away from the substrate upper side 11 so that a direct contact between the current-conducting rails 210 and the anode 21 is ensured. The active organic layer 20 is arranged downstream of the anode 21, wherein the active organic layer extends in parallel with the substrate upper side 11. Unlike in FIG. 1, the active organic layer 20, with the exception of relatively small surface wrinklings or structurings which are predetermined, e.g., by the transparent anode 21, extends in a planar or flat manner and in particular in a plane-parallel manner with respect to the substrate upper side 11.

In FIG. 2, the insulating material 25 is not applied to the current-conducting rails 210, but rather is arranged in the form of rails between the active organic layer 20 and the cathode 22. In a plan view of the substrate upper side 11, the rails of the insulating material 25 are, e.g., congruent or overlap by at least 95% with the current-conducting rails 210. The cathode 22 is placed over the rails of the insulating material 25 such that in the emission regions 5 the cathode 22 lies on the active organic layer 20 and in the region of the rails of the insulating material 25 the cathode lies on the rails.

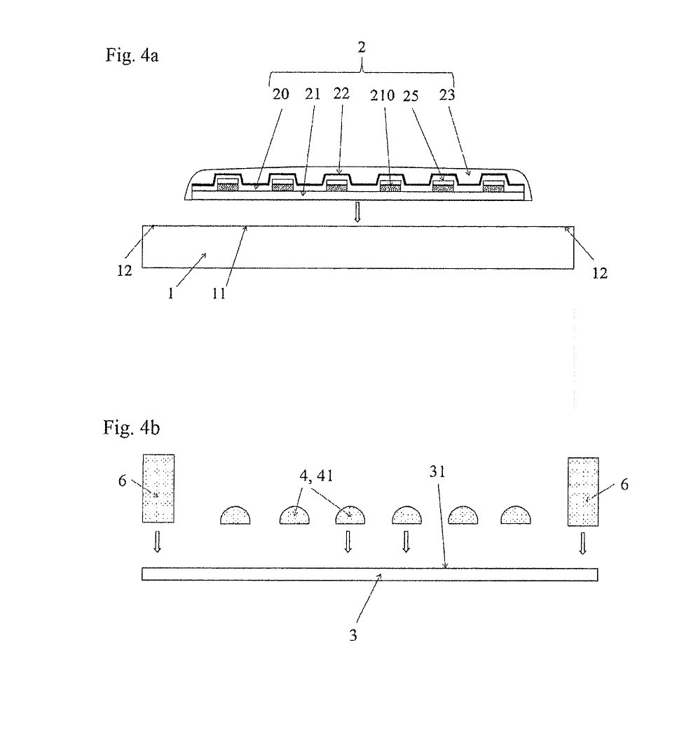

FIG. 3a shows a section of the light-emitting device 100 in a plan view of the substrate upper side 11. In the example in accordance with FIG. 3a, the current-conducting rails 210 are arranged in a grid, wherein three current-conducting rails 210 intersect at a common intersection point 211. The three current-conducting rails 210 extend in parallel with their respective main extension direction T_{S}. The current conducting rails 210 comprise a width B_{S} perpendicular to the main extension directions T_{S}. Furthermore, the example in FIG. 3a shows spacers 4 that partly cover the current-conducting rails 210. The width B_{A} of the spacers 4, as measured perpendicularly with respect to the respective main extension direction T_{S} is greater than the width B_{S} of the current-conducting rails 210. In particular, in the example of FIG. 3a, the spacers 4 cover the current-conducting rails 210 over their entire width B_{S}. The width B_{A} of the spacers 4 is at the most twice or at the most 1.5 times or at the most 1.3 times the width B_{S} of the current-conducting rails 210. Alternatively or in addition, the width B_{A} of the spacers 4 is at least 0.5 times or 0.7 times or 0.9 times the width B_{S} of the current-conducting rails 210.

In FIG. 3a, the spacers 4 cover the current-conducting rails 210 only in sub-regions. Alternatively, it is also possible, however, for the spacers 4 to cover, e.g., at least 90% of all of the current-conducting rails 210. For this purpose, the spacers 4 could comprise a grid structure identical or similar to the grid structure of the current-conducting rails 210. For example, a hexagonal grid structure would thus be possible for the spacers 4.

FIG. 3b illustrates an example of the entire light-emitting device 100, wherein the device 100 is viewed in a plan view of the substrate upper side 11. The substrate 1 comprises a hexagonal cross-sectional shape. The layer sequence 2 is applied to the substrate upper side 11, wherein edge regions 12 of the substrate upper side 11 are free from the layer sequence 2. The layer sequence 2 forms a contiguous surface without interruptions or inclusions and comprises a circular cross-sectional shape. The edge regions 12 of the substrate upper side 11 are covered with an adhesive layer 6. The adhesive layer 6 forms a path extending around the entire layer sequence 2 without any interruptions so that the layer sequence 2 is defined by the adhesive layer 6 in all directions in parallel with the substrate upper side 11. The encapsulation glass 31 (not shown in FIG. 3b) is placed onto the adhesive layer 6. As a result, the region surrounded by the adhesive layer 6 and in which the layer sequence 2 is also arranged produces, e.g., a closed, air-tight region.

In FIG. 3b, current-conducting rails 210 arranged in a hexagonal grid and intersecting at intersection points 211 are introduced into the layer sequence 2. Furthermore, in FIG. 3b the spacers 4 are formed as buffer points 41 which in a plan view of the substrate upper side 11 comprise in particular a circular cross-sectional shape. Every two adjacent buffer points 41 are separated and spaced apart from one another, e.g., spaced apart by 3 mm. Furthermore, the buffer points 41 are arranged matrix-like on the encapsulation glass underside 31 so that in a plan view of the substrate upper side 11 the buffer points 41 completely cover the intersection points 211 of the current-conducting rails 210.

In the example in accordance with FIG. 3b, the lateral extent of the buffer points 41 in parallel with the encapsulation glass underside 31 is, e.g., 100 μm. In the event of a mechanical loading on the device 100 in FIG. 3b, contact between the buffer points 41 and the layer sequence 2 advantageously occurs only in the region of the intersection points 211 of the current-conducting rails 210. In this case, on the one hand the stability of the device 100 can be particularly high, on the other hand these regions are preferably not provided for radiation emission. The emission regions 5 arranged between the current-conducting rails 210 and in FIG. 3b have hexagonal cross-sectional shapes advantageously remain free of damage.

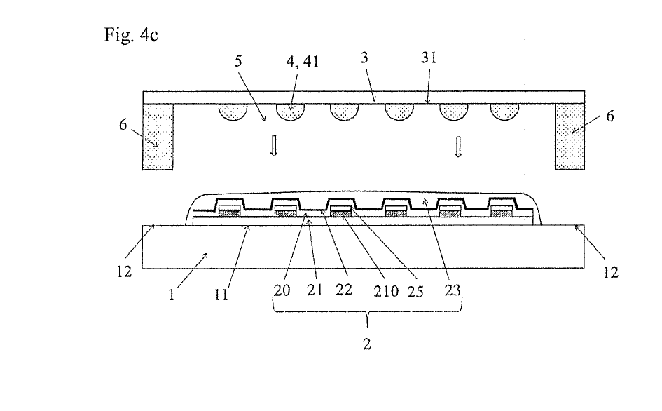

The side views of examples of the device 100 as illustrated in FIGS. 1 and 2 and in FIGS. 4a to 4c are viewed, e.g., along the cross-sectional line AA′ in FIG. 3b.

FIG. 4a shows an example of a method step of producing the light-emitting device 100. A layer sequence 2 is applied to the substrate upper side 11 of the substrate 1. Edge regions 12 which adjoin the lateral surfaces of the substrate 1 remain free from the layer sequence 2. Unlike as shown in the example of FIG. 4a, the layers of the layer sequence 2 are generally not applied in one method step, but rather consecutively.

FIG. 4b illustrates a further method step of producing the light-emitting device 100. The adhesive layer 6 and the spacers 4 or the buffer points 41 are deposited on the encapsulation glass underside 31 of the encapsulation glass 3. The adhesive layer 6 and the spacers 4 can be applied simultaneously in a common screen printing method. This is possible in particular if the adhesive layer 6 and the spacers 4 comprise the same material or consist of the same material.

After applying the adhesive layer 6 and the spacers 4 to the encapsulation glass 3, the encapsulation glass 3 and the substrate 1 connect together as shown in FIG. 4c. The substrate upper side 11 and the encapsulation glass underside 31 are turned towards one another. When the substrate 1 and the encapsulation glass 31 are being joined together, in particular the adhesive layer 6 is arranged in the edge region 12 of the substrate upper side 11. Furthermore, the joining procedure is effected such that in a plan view of the substrate upper side 11 the spacers 4 partly cover the current-conducting rails 210. The encapsulating glass 3 and the substrate 1 are preferably joined together under an inert gas atmosphere, e.g., in the presence of a noble gas such as argon or helium. This advantageously prevents undesired foreign particles from being enclosed in an intermediate space between the substrate 1 and the encapsulation glass 3.

Our methods and devices described herein are not limited by the description made with reference to the examples. Rather, the disclosure encompasses any new feature and any combination of features, including in particular any combination of features in the appended claims, even if the feature or combination is not itself explicitly indicated in the claims or examples.

This application claims priority of DE 10 2014 100 770.0, the subject matter of which is incorporated herein by reference.

1-16 (canceled)

17. A light-emitting device comprising:
a substrate having a substrate upper side;
a layer sequence arranged on the substrate upper side and having at least one active, light-emitting, organic layer, wherein the layer sequence comprises a plurality of emission regions that emit light;
current-conducting rails which are a part of the layer sequence, wherein, in a plan view of the substrate upper side, the emission regions of the layer sequence are arranged next to the current-conducting rails;
an encapsulation glass, wherein the layer sequence is arranged between the substrate and the encapsulation glass; and
spacers formed as elevations on an encapsulation glass underside and facing towards the layer sequence of the encapsulation glass, wherein,
in a plan view of the substrate upper side, the spacers at least partly overlap with the current-conducting rails, and the spacers prevent direct contact between the encapsulation glass and the layer sequence in the emission regions.

18. The light-emitting device according to claim 17, wherein
the spacers are formed as buffer points, wherein the buffer points are mutually spaced-apart, dome-shaped elevations arranged in matrix in a regular pattern on the encapsulation glass underside, and
the current-conducting rails intersect at intersection points and, in a plan view of the substrate upper side, the buffer points at least partly overlap with the intersection points of the current-conducting rails.

19. The light-emitting device according to claim 17, wherein
the current-conducting rails are embedded in the substrate,
the light-emitting device comprises a first electrode and a second electrode,
the second electrode is arranged downstream of the active organic layer in a direction away from the substrate upper side, and
insulating material is arranged in the form of rails between the active organic layer and the second electrode so that, in a plan view of the substrate upper side, the current-conducting rails at least partly overlap with the insulating material.

20. The light-emitting device according to claim 17, wherein the current-conducting rails are arranged between the active organic layer and the substrate.

21. The light-emitting device according to claim 17, wherein
the layer sequence comprises an anode, wherein
the anode is arranged between the current-conducting rails and the substrate,
the anode comprises a different material than the current-conducting rails and is transparent to the light emitted by the active organic layer,
the layer sequence comprises a cathode, and
the cathode is arranged downstream of the active organic layer in a direction away from the substrate upper side and is formed to be reflective to the light emitted by the active organic layer.

22. The light-emitting device according to claim 17, wherein the spacers are at least temporarily not in direct contact with the layer sequence.

23. The light-emitting device according to claim 17, wherein the spacers are at least partly in direct contact with the layer sequence in the region of the current-conducting rails.

24. The light-emitting device according to claim 17, wherein the layer sequence has a lateral extent in parallel with the substrate upper side of 2 cm to 35 cm,
the buffer points have a lateral extent along the encapsulation glass underside of 50 μm to 300 μm and a thickness of 10 μm to 50 μm,
the current-conducting rails have a width of 60 μm to 150 μm and a thickness of 3 μm to 6 ∥m, and
the spacing between two adjacent intersection points of the current-conducting rails is 1 mm to 5 mm.

25. The light-emitting device according to claim 17, further comprising:
an edge region of the substrate upper side at least partly free from the layer sequence; and
an adhesive layer applied in the edge region to the substrate upper side, wherein the adhesive layer contacts the encapsulation glass underside and mechanically connects the substrate to the encapsulation glass.

26. The light-emitting device according to claim 25, wherein the adhesive layer comprises a thickness of 10 μm to 80 μm and has a lateral extent along the substrate upper side of 1 mm to 2 cm.

27. The light-emitting device according to claim 25, wherein the adhesive layer and the spacers consist of the same material, and the material of the adhesive layer and the spacers is different from the material of the encapsulation glass.

28. The light-emitting device according to claim 17, wherein an absorption material is introduced between the layer sequence and the encapsulation glass and absorbs oxygen and/or water.

29. The light-emitting device according to claim 17, wherein the layer sequence comprises a thin-film encapsulation at least partly covering all of the sides of the layer sequence not covered by the substrate upper side, and the thin-film encapsulation comprises a layer thickness of 50 nm to 1000 nm and protects the layer sequence against reactions with the surrounding area.

30. The light-emitting device according to claim 17, wherein at least one side of the current-conducting rails facing away from the substrate is covered with an insulating material.

31. A light-emitting device comprising:
a substrate having a substrate upper side;
a layer sequence arranged on the substrate upper side and having at least one active, light-emitting, organic layer, wherein the layer sequence comprises a plurality of emission regions that emit light;
current-conducting rails which are a part of the layer sequence, wherein, in a plan view of the substrate upper side, the emission regions of the layer sequence are arranged next to the current-conducting rails, and the current-conducting rails intersect at intersection points;
an encapsulation glass, wherein the layer sequence is arranged between the substrate and the encapsulation glass;
spacers formed as elevations on an encapsulation glass underside and facing towards the layer sequence of the encapsulation glass, wherein the spacers are formed as buffer points,
wherein the buffer points are mutually spaced-apart, dome-shaped elevations arranged in a matrix in a regular pattern on the encapsulation glass underside,
in a plan view of the substrate upper side, each spacer at least partly overlaps with an intersection point of the current-conducting rails, and
the spacers prevent direct contact between the encapsulation glass and the layer sequence in the emission regions.

32. A method of producing the light-emitting device according to claim 17, comprising:
providing a substrate having a substrate upper side;
applying a layer sequence to the substrate upper side, wherein an edge region of the substrate upper side is provided at least partly to be free from the layer sequence;
providing an encapsulation glass having an encapsulation glass underside;
applying an adhesive layer to the encapsulation glass underside;
applying spacers to the encapsulation glass underside so that the spacers are bordered by the adhesive layer; and
joining the substrate and the encapsulation glass together so that the substrate upper side and the encapsulation glass underside face towards one another and the adhesive layer is arranged in the edge region of the substrate upper side.

33. The method according to claim 32, wherein the spacers and the adhesive layer comprise the same material and are applied to the encapsulation glass underside in a common screen printing process.

34. The method according to claim 32, wherein applying the layer sequence includes an intermediate step of applying a grid of current-conducting rails.

35. The method according to claim 34, wherein the spacers are applied such that after the substrate and the encapsulation glass have been joined together, said spacers partly cover the current-conducting rails of the layer sequence in a plan view of the substrate upper side.
